(19) United States
(12) Patent Application Publication
(10) Pub. No.: US 2025/0014794 A1
(43) Pub. Date: Jan. 9, 2025

(54) POWDER METALLURGICAL APPROACH TO A CoFe - AL2O3 SOFT MAGNETIC COMPOSITE

(71) Applicants: The Regents of the University of California, Oakland, CA (US); Sandia National Laboratory, Albuquerque, NM (US)

(72) Inventors: Enrique J. Lavernia, Oakland, CA (US); Baolong Zheng, Oakland, CA (US); Calvin Belcher, Oakland, CA (US); Todd Monson, Albuquerque, NM (US)

(73) Assignees: The Regents of the University of California, Oakland, CA (US); Sandia National Laboratory, Albuquerque, NM (US)

(21) Appl. No.: 18/587,841

(22) Filed: Feb. 26, 2024

Related U.S. Application Data
(60) Provisional application No. 63/448,657, filed on Feb. 27, 2023.

(51) Int. Cl. H01F 1/24; B22F 1/16; C23C 16/40

(52) U.S. Cl. CPC H01F 1/24; B22F 1/16; C23C 16/403; B22F 2301/35; B22F 2302/253; B22F 2304/10

(57) ABSTRACT

The present embodiments relate to a soft magnetic composite synthesized via spark plasma sintering with both high saturation magnetic polarization and high electrical resistivity for efficient soft magnetic cores. CoFe powder particles coated with an insulating layer of Al₂O₃ were used as feedstock material to improve the electrical resistivity while retaining high saturation magnetic polarization. By maintaining a continuous non-magnetic Al₂O₃ phase throughout the material, both a high saturation magnetic polarization, above 1.5 T, and high electrical resistivity, above 100 μΩ·m, were achieved. Through microstructural characterization of samples consolidated at various temperatures, the role of microstructural evolution on the magnetic and electronic properties of the composite was elucidated. Upon consolidation at relatively high temperature, the CoFe was found to plastically deform and flow into the Al₂O₃ phase at the particle boundaries and this phenomenon was attributed to low resistivity in the composite. In contrast, at lower consolidation temperatures, perforation of the Al₂O₃ phase was not observed and a high electrical resistivity was achieved, while maintaining a high magnetic polarization.

### CROSS-REFERENCE TO RELATED APPLICATIONS

This application claims priority to U.S. Provisional Patent Application No. 63/448,657 filed Feb. 27, 2023, the contents of which are incorporated by reference herein in their entirety.

### STATEMENT OF GOVERNMENT SPONSORED RESEARCH

This invention was made with government support under Grant Number DE-AR0001020, awarded by the Department of Energy. The Government has certain rights in the invention.

### TECHNICAL FIELD

The present embodiments relate generally to soft magnetic materials and more particular to a soft magnetic composite material exhibiting properties which may improve efficiency of transformer cores needed for power conversion, transmission, and generation.

### BACKGROUND

More efficient power conversion devices, particularly transformers are needed for power grids to meet the global demands for increased energy consumption. Transformers and other power conversion devices such as motors and inductors rely on magnetic cores which must be made of soft magnetic materials. Current soft magnetic materials such as the binary CoFe alloy have high saturation magnetic polarization, but often have low electrical resistivity and poor mechanical properties. So, soft magnetic materials which have high saturation magnetic polarization and high electrical resistivity and favorable mechanical properties are needed.

It is against this technological backdrop that the present Applicant sought a technological solution to these and other problems rooted in this technology.

### SUMMARY

The present embodiments relate generally to a CoFe—Al₂O₃ soft magnetic composite that achieves both high saturation magnetic polarization and high electrical resistivity. The composite of the present embodiments is made up of CoFe and Al₂O₃ through powder metallurgical processing. This composite concept has unique properties due to the relatively thick Al₂O₃ coating on CoFe powders which acts as an electrically insulative barrier between powder particles. The coated powders are consolidated using a specific sintering process. The sintering process of embodiments enables the net-shape fabrication of this composite for large scale magnetic core component manufacturing.

### BRIEF DESCRIPTION OF THE DRAWINGS

These and other aspects and features of the present embodiments will become apparent to those ordinarily skilled in the art upon review of the following description of specific embodiments in conjunction with the accompanying figures, wherein:

FIGS. 1(a) to 1(e) illustrate aspects of embodiments: (a) a BSE micrograph depicting an as-coated Al₂O₃-coated CoFe powder particle and its grains and (b) a lower-magnification BSE micrograph and (c-e) corresponding EDS elemental maps showing the Al₂O₃ coating fully surrounding the CoFe powder particles.

FIGS. 2(a) and 2(b) illustrate additional aspects of embodiments: (a) XRD patterns comparing the as-received gas atomized CoFe powders, the as-coated Al₂O₃-coated CoFe, and the coated powders consolidated at 700° C. and 1000° C. and (b) a closer view of the Al₂O₃XRD peaks.

FIGS. 3(a) to 3(d) illustrate additional aspects of embodiments: (a) a BSE micrograph of 1000° C. consolidated CoFe-Al₂O₃ composite and (b-d) corresponding EDS elemental maps depicting the Al₂O₃ coating fully surrounding the CoFe powder particles.

FIGS. 4(a) to 4(e) illustrate additional aspects of embodiments: (a) a Higher-magnification SE micrograph and corresponding (b) BSE micrograph and EDS elemental maps of (c) Al, (d) Co, and (e) Fe. Some regions where CoFe appears perforating the Al₂O₃ coating regions, are circled in red.

FIGS. 5(a) to 5(d) illustrate additional aspects of embodiments: (a) a BSE micrograph and (b-d) corresponding EDS elemental maps of the 700° C. consolidated CoFe-Al₂O₃ composite, showing the distinct, continuous Al₂O₃ coating surrounding CoFe powder particles.

FIGS. 6(a) and 6(b) illustrate additional aspects of embodiments: (a) Higher-magnification SE micrograph and (b) corresponding BSE micrograph of the 700° C. consolidated composite, showing non-uniform porosity and voids in the Al₂O₃ coating surrounding CoFe powder particles. Some of the porosity in the powder particles is denoted by black arrows.

FIGS. 7(a) and 7(b) illustrate example magnetic hysteresis curves of the CoFe-Al₂O₃SMC after consolidation at (a) 1000° C. and (b) 700° C. The insets in each plot show a narrower range of the B-H loop to observe the coercivity of each SMC.

### DETAILED DESCRIPTION

The present embodiments will now be described in detail with reference to the drawings, which are provided as illustrative examples of the embodiments so as to enable those skilled in the art to practice the embodiments and alternatives apparent to those skilled in the art. Notably, the figures and examples below are not meant to limit the scope of the present embodiments to a single embodiment, but other embodiments are possible by way of interchange of some or all of the described or illustrated elements. Moreover, where certain elements of the present embodiments can be partially or fully implemented using known components, only those portions of such known components that are necessary for an understanding of the present embodiments will be described, and detailed descriptions of other portions of such known components will be omitted so as not to obscure the present embodiments. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the present disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present embodiments encompass present and future known equivalents to the known components referred to herein by way of illustration.

### INTRODUCTION

According to some initial aspects, the present embodiments relate to a CoFe—Al₂O₃ composite that is produced by consolidating Al₂O₃ coated CoFe powder particles via spark plasma sintering, targeting a soft magnetic composite with high saturation magnetic polarization and high electrical resistivity. The powder particles were coated with a large-scale, coating deposition process, and had a thickness of ˜4 μm. The composite consolidated at 700° C. displayed an exceptional combination of a high saturation magnetic polarization of 1.88 T, and high electrical resistivity 135 μOhm·m. The properties were attributed to the SMC having relatively low density in the Al₂O₃ and a continuous Al₂O₃ coating surrounding CoFe powder particles. Further densification of the CoFe-Al₂O₃ composite after consolidation at 700° C., without uncontrolled percolation of the CoFe phase into the Al₂O₃ phase, may further improve magnetic properties of the composite.

The soft magnetic composite developed in this work can be used to achieve more efficient transformer cores and electrical machines compared to state of the art materials such as Si Steels and CoFe alloys. Additionally, the synthesis approach used in this work to develop this soft magnetic composite allows for larger scale production compared to current state of the art composites. The composite developed in this work is less expensive and can also be operated at temperatures higher than composites with polymer coatings.

This CoFeAl₂O₃ soft magnetic composite is in the experimental and prototyping stage. The latest experimental samples had a saturation magnetic polarization of ˜1.88 T and electrical resistivity of ˜135 μOhm*m. These properties can be improved with further process optimization.

As mentioned above, among other things, the present Applicant recognizes that more efficient power conversion devices, particularly transformers are needed for power grids to meet the global demands for increased energy consumption. Transformers and other power conversion devices such as motors and inductors rely on magnetic cores which must be made of soft magnetic materials (Callister W, Rethwisch D (2010) Materials science & engineering an introduction, 8th edn. Wiley, Hoboken; Cullity B D, Graham C D (2009) Introduction to magnetic materials, 2nd edn. Wiley, Piscataway; Silveyra J M, Ferrara E, Huber D L, Monson T C (2018) Soft magnetic materials for a sustainable and electrified world. Science 362: eaao0195 https://doi.org/10.1126/science.aa 00195). Soft magnetic materials are not necessarily mechanically soft, but are magnetically soft, meaning the induced magnetic polarity in the material can be easily switched by an applied field and the material has relatively low magnetic coercivity (Hc\1000 A/m) (Id.). Some of the applied magnetic field is required to overcome the material's coercivity before a polarity can be induced in the material, causing magnetic power losses. To minimize magnetic power losses, low coercivity in soft magnetic materials must be achieved. Eddy current losses are another major source of power losses. Eddy current losses come from eddy currents produced in the core material by the switching magnetic polarity of the magnetic core. Eddy current losses can be approximated using Eq. (1) from Narasimhan, K. S.: Magnetic Materials and properties for powder metallurgy part applications. In: Samal, P., Newkirk, J. (eds.), Powder Metall. ASM Handb., 7th ed., ASM International, pp. 737-754 (2018). https://doi.org/10.31399/a sm.hb.v07.a0006057:

$${P}_{e} ∝ \frac{{d}^{2} {B}^{2} {f}^{2}}{ρ} \qquad ( 1 )$$

Eddy current losses (Pe) are inversely proportional to the electrical resistivity (q) of the core material. B is the magnetic induction in the material, f is the frequency of operation of the power conversion device, and d is the electrical domain size, or effective scale of the eddy currents (Krishnan K M (2016) Fundamentals and applications of magnetic materials, 1st edn. Oxford University Press, Oxford). To minimize eddy current losses, high electrical resistivity and small eddy current domain size are necessary in a core material. Soft magnetic materials used as magnetic cores must also possess high saturation magnetic polarization (Jₛ₋>1.0 T) to allow conversion devices to operate with greater power densities, converting more power with smaller core volumes. An ideal soft magnetic core should have low coercivity, high electrical resistivity, and high saturation magnetic polarization. The challenge in many state of the art soft magnetic materials, such as Si steels, has been achieving ideal magnetic properties and high electrical resistivity due to the metallic nature of most soft magnetic materials (Ouyang G, Chen X, Liang Y, Macziewski C, Cui J (2019) Review of Fe-6.5 wt. % Si high silicon steel—a promising soft magnetic material for sub-kHz application. J Magn Magn Mater 481:234-250. https://doi.org/10.1016/j.jmmm. 2019.02.089). Si steels have a moderately high Jₛ around 1.8-2.0 T, but low electrical resistivity, approximately 0.5-0.8 μΩ·m (Id.). To reduce eddy current losses, Si steel cores are often produced as laminated sheets, effectively minimizing eddy current domain size to the thickness of individual Si steel sheets. Recently, composite materials with a soft magnetic metallic phase and an electrically insulating phase have been explored to produce more efficient soft magnetic core materials with high Jₛ and high electrical resistivity. Development of soft magnetic composites (SMCs) as a design approach to more efficient soft magnetic cores began in the 1990s and gained notoriety for their potential to significantly minimize magnetic energy losses. SMCs can potentially achieve high Jₛ, low coercivity, and high electrical resistivity, necessary to maximize power density and minimize magnetic energy losses, when a magnetically ordered phase is properly intermixed with a non-magnetic, electrically insulating phase (Pe'rigo EA, Weidenfeller B, Kolla'r P, Füzer J (2018) Past, present, and future of soft magnetic composites. Appl Phys Rev 5: 031301. https://doi.org/10.1063/1.5027045; Sunday K J, Taheri M L (2017) Soft magnetic composites: recent advancements in the technology. Met Powder Rep 72:425-429. https://doi.org/10.1016/j.mprp.2016.08.003; Shokrollahi H, Janghorban K (2007) Soft magnetic composite materials (SMCs). J Mater Process Technol 189:1-12. https://doi.org/10.1016/j.jmatprotec.2007.02.034; Yu R H, Basu S, Ren L, Zhang Y, Parvizi-Majidi A, Unruh K M, Xiao J Q (2000) High temperature soft magnetic materials: FcCO alloys and composites. IEEE Trans Magn 36:3388-3393 https://doi.org/10.1109/20.908809)

As noted in Eq. (1), by increasing the bulk electrical resistivity and by reducing d, electrical domain size of eddy currents of a soft magnetic material, the eddy current losses of the material are reduced. SMCs can achieve high bulk electrical resistivity and reduced electrical domain sizes by fully intersecting a magnetic phase with a continuous phase which is nonmagnetic and electrically insulating. Ultimately, the achievable magnetic properties of a SMC are limited by the volume fraction, morphology, and distribution, of the non-magnetic, insulating phase. The insulating phase in the SMC acts as a distributed air gap, and if not properly controlled, a high volume fraction of the non-magnetic phase detrimentally increases coercivity and reduces Jₛ by physically separating and inhibiting magnetic interaction between the magnetic phase. Compared to discontinuously distributed non-magnetic fibers or particles, a continuous non-magnetic phase intersecting dispersed particles of a magnetic phase has been shown to be more effective at tailoring the magnetic and electronic properties of SMCs. A continuous phase prevents long range charge carrier transport and more effectively increases the measured resistivity of the SMC. Additionally, the thickness of the continuous phase between magnetic particles can be adjusted to tailor the magnetic interaction of the particles and thus the magnetic behavior of the SMC. The volume fraction, morphology, and distribution of the magnetic phase in an SMC can be adjusted to maintain high Jₛ and low coercivity, and achieve high electrical resistivity. Development of SMCs and their microstructures can potentially achieve more efficient properties for soft magnetic cores. One of the most broadly effective and practical approaches to SMC development has been the consolidation of coated ferromagnetic powder particles. Ferromagnetic powders maximize the achievable Jₛ in SMCs and can be coated with an insulating layer to reliably restrict charge carrier movement in the bulk, consolidated SMC. Once consolidated, the coatings on the powder particles form a continuous phase, intersecting the ferromagnetic particles. By selecting powder particle sizes (typically on the range of 5-200 μm) and controlling the powder coating thickness, the bulk volumetric phase fraction of the insulating phase can be adjusted.

In related studies, Fe powders have been coated with organic polymers such as epoxies and resins, allowing the coated powders to be densified with relatively low consolidation pressures and temperatures. Organic polymer SMCs yielded moderate resistivity, on the order of 100 μΩ·m, but typically are not thermally stable above 300° C. and have low Jₛ, less than 1.0 T (Svensson L, Frogner K, Jeppsson P, Cedell T, Andersson M (2012) Soft magnetic moldable composites: properties and applications. J Magn Magn Mater 324:2717-2722. https://d oi.org/10.1016/j.jmmm.2012.03.049; Dias M M, Mozetic H J, Barboza J S, Martins R M, Pelegrini L, Schaeffer L (2013) Influence of resin type and content on electrical and magnetic properties of soft magnetic composites (SMCs). Powder Technol 237:213-220. https://doi. org/10.1016/j.powtec.2013.01.006). In other approaches, consolidated SMCs made with coatings of Al₂O₃, SiO₂, or even CaF₂ on ferromagnetic powder particles reached high resistivities on the order of 100-1000μQ·m, and moderate Jₛ, approximately 1.0-1.5 T (Sugimura K, Miyajima Y, Sonchara M, Sato T, Hayashi F, Zettsu N, Teshima K, Mizusaki H (2016) Formation of high electrical-resistivity thin surface layer on carbonyl-iron powder (CIP) and thermal stability of nanocrystalline structure and vortex magnetic structure of CIP. AIP Adv 6: 055932. https://doi.org/10.1063/1.4944705; Ishizaki T, Nakano H, Tajima S, Takahashi N (2017) Improving powder magnetic core properties via application of thin, insulating silica-nanosheet layers on iron powder particles. Nanomaterials 7:1-13. https://doi.org/10.3390/na no7010001; Zheng J, Zheng H, Lei J, Ying Y, Qiao L, Cai W, Li W, Yu J, Tang Y, Che S (2020) Magnetic properties and microstructure of iron-based soft magnetic composites with Al₂O₃ insulating coating by one-pot synthesis method. J Magn Magn Mater 499: 166255. https://doi.org/10.1016/j.jmmm.2 019.166255; Sunday K J, Darling K A, Hanejko F G, Anasori B, Liu Y C, Taheri M L (2015) Al₂O₃ ‘self-coated’ iron powder composites via mechanical milling. J Alloys Compd 653:61-68. https://doi.org/10.1016/j.jallcom.2015.08.260; Peng Y, Yi Y, Li L, Yi J, Nie J, Bao C (2016) Iron-based soft magnetic composites with Al₂O₃ insulation coating produced using sol-gel method. Mater Des 109:390-395. http s://doi.org/10.1016/j.matdes.2016.07.097; Ouyang G, Jensen B, Tang W, Schlagel J, Hilliard B, Pan C, Cui B, Dennis K, Jiles D, Monson T, Anderson I, Kramer M J, Cui J (2020) Near net shape fabrication of anisotropic Fe-6.5% Si soft magnetic materials. Acta Mater 201:209-216. https://doi.org/10.1016/j.actamat.2020.09.084; Choi S, Lec S, Bon C Y, Lec K H, Choi S J, Yoo S I (2021) Novel fabrication method for a high-performance soft-magnetic composite composed of alumina-coated Fe-based metal powder. J Electron Mater 50:664-674. https://doi.org/10.10 07/s11664-020-08607-8; Tajima S, Hattori T, Kondoh M, Kishimoto H, Sugiyama M, Kikko T (2005) Properties of high density magnetic composite (HDMC) fabricated from iron powder coated with new type phosphate insulator. IIEEE Trans Magn 41:267. H ttps://doi.org/10.1109/intmag.2005.1463695; Liu D, Wu C, Yan M (2015) Investigation on sol-gel Al₂O₃ and hybrid phosphate-alumina insulation coatings for FeSiAl soft magnetic composites. J Mater Sci 50:6559-6566. https://doi.org/10.1007/s10853-015-9189-4; Zhou B, Dong Y, Liu L, Chang L, Bi F, Wang X (2019) Enhanced soft magnetic properties of the Fe—based amorphous powder cores with novel TiO2 insulation coating layer. J Magn Magn Mater 474:1-8. https://doi.org/10.1016/j.jmmm.2018.11.014). The high resistivity of Al₂O₃ containing SMCs is attributed to the high electrical resistivity of Al₂O₃, on the order of 1017μΩ·m. Additionally, the Al₂O₃ phase has a higher thermal stability than organic polymers and other insulating phases such as phosphates or fluorides which may degrade at comparably lower temperatures (Yamano Y, Komiyama T, Takahashi M, Kobayashi S, Nitta K, Saito Y (2008) “Measurement of surface and volume resistivity for alumina ceramics under vacuum condition. Proc Int Symp Discharges Electr Insul Vacuum ISDEIV 1:35-38. https://doi.org/10.1109/DEIV.2008.4676711; Auerkari P (1996) Mechanical and physical properties of engineering alumina ceramics. In: VTT Tied.—Valt. Tek. Tutkimusk). However, the processes used to coat powders with Al₂O₃ are relatively of small scale and have not enabled large production volumes of SMCs. Furthermore, the ceramic coating on metal powders requires higher temperatures and thus longer sintering and consolidation times, allowing equilibrium structures to form which may hinder magnetic and electronic properties. Large-scale and thick powder coating deposition techniques and consolidation processes are necessary to develop more efficient SMCs for power conversion device cores.

In recent years, commercial coating deposition techniques have been developed to effectively coat large batches of metal powders with thick ceramic coatings. Industrially developed processes can produce several kilograms of powders with uniform, micrometers thick Al₂O₃ coatings reacted and deposited onto the surfaces which can be consolidated into SMCs with controlled microstructures and properties. Non-equilibrium spark plasma sintering (SPS) consolidation processes have been developed over the years and can rapidly consolidate both metal and ceramic powders. Similar to conventional sintering, SPS is a field activated, diffusional process, which causes coalescence of powders across interfaces to form a dense, bulk body. Compared to conventional sintering, the rapid heating rates and short sinter times associated with SPS can be used to fully densify materials with minimal grain growth. In the case of SMCs, SPS can be used to rapidly consolidate metal powders coated with a ceramic while avoiding the formation of new phases or mixing of the constituent elements which may degrade the final properties of the SMC (Garay J E (2010) Current-activated, pressure-assisted densification of materials. Annu Rev Mater Res 40:445-468. Https://doi.org/10.1146/annurev-matsci-070909-104433; Dupuy A, Zheng B, Zhou Y, Delplanque J, Monson T, Lavernia E J, Schoenung J M (2019) Consolidation and behavior of FeCoV soft magnetic materials via spark plasma sintering. In: Cavaliere P (ed) Spark Plasma Sinter. Mater. Springer, Lecce, pp 473-491. https://doi.org/10.1007/978-3-030-05327-7). In addition to more robust powder coating and consolidation techniques, ferromagnetic powders with improved soft magnetic properties can be used as the feedstock powder to achieve higher Jₛ.

In view of the above challenges, an aspect of the present embodiments involved an investigation of the feasibility of using a powder consolidation approach to synthesize a soft magnetic composite material and to investigate the resultant magnetic and electronic characteristics. To accomplish this objective, instead of Fe, in one example approach the equiatomic CoFe alloy which has significantly higher Jₛ was used as the ferromagnetic powder to maintain high Jₛ and low He in SMCs (Sourmail T (2005) Near equiatomic FeCo alloys: Constitution, mechanical and magnetic properties. Prog Mater Sci 50:816-880. https://doi.org/10.1016/j.pmatsci.2005.04.001). Moreover, a large-scale deposition process was used to coat a large volume of CoFe powder particles with Al₂O₃ which were then subsequently densified using SPS consolidation. To produce a large volume of powders with a thick coating, on the order of several micrometers, the CoFe powders were coated by a vendor using a commercial, proprietary process which chemically reacts Al₂O₃ onto the surfaces of a fluidized bed of CoFe powders. After this coating process, a fully dense SMC with a CoFe-Al₂O₃ core-shell structure with particles of the CoFe phase fully separated by a continuous Al₂O₃ phase was then targeted by consolidating the coated CoFe powders using SPS to achieve high Jₛ, above 2.0 T, and high electrical resistivity, above 1.0μΩ·m.

### Example Materials and Methods

Gas atomized, pre-alloyed equiatomic CoFe powder particles, with a particle size below 150 μm, were purchased from Oryx Advanced Materials (Fremont, CA, USA) and were used as the feedstock powder to be coated with Al₂O₃. Approximately 1 kg of CoFe powder particles in the range of 20-150 μm were coated with 2 vol. % Al₂O₃ (2-5 μm thick) by Advanced Powder Solutions, Inc (Cypress, TX, 77,429 USA) with a proprietary chemical vapor deposition process. Using a Fuji SPS-825S DR. SINTER (Fuji Electronic Industrial Co., Ltd., Kawasaki, Japan) SPS with a maximum pulsed DC output of 12 V and 8000 A, the as-coated powders were consolidated at 700° C. and 1000° C. under a vacuum of less than 5 Pa to form 5 mm OD×2 mm HT samples. During SPS consolidation, the uniaxial load was manually held at the lower limit of the SPS, to stay below a compressive stress of 150 MPa. The samples were then polished for magnetic properties measurements and cross sectioned for microstructural characterization.

The Archimedes method was used to measure the density of as-consolidated SMC disks. To assess the relative density the measured density was compared to the theoretical density of a BCC CoFe structure with 2 vol. % Al₂O₃. The phase composition of the as received powders and consolidated SMCs was assessed with a Rigaku SmartLab X-ray diffractometer (XRD) equipped with a Cu Kₐ (λ=0.1542 nm) radiation source. As-received coated powders were mounted in KonductoMet™ and mechanically polished to 0.04 μm to evaluate the microstructural features of the cross sections of powders. The consolidated SMCs were cross-sectioned using wire electronic discharge machining (EDM). They were mechanically polished to 0.04 μm to evaluate the microstructural features in the cross-section of the SMCs, perpendicular to the SPS loading direction. The microstructures of cross-sectioned as-coated powders and consolidated SMCs were characterized using a FEI Quanta 3D field emission gun scanning electron microscope (SEM) equipped with an Everhart Thornley secondary electron (SE) detector, a pole piece mounted backscatter electron (BSE) detector and an Oxford energy-dispersive X-ray spectrometer (EDS). ImageJ software was used to measure grain sizes and coating thicknesses. All micrographs of the consolidated disks are normal to the uniaxial SPS loading direction.

The magnetic and electronic properties of the consolidated disks were measured at Sandia National Laboratories (Albuquerque, NM, USA). To evaluate the Jₛ and coercivity of the consolidated disks, the magnetic properties were measured using a Quantum Design MPMS-7 superconducting quantum interference device (SQUID) magnetometer. Magnetization curves were recorded from −7 T to +7 T at 293 K. To more accurately measure the effects of the Al₂O₃ coating and avoid surface defects from the consolidation and polishing process, the electrical resistivity through the height of the consolidated disks was measured. To measure resistivity through the height of the consolidated disks, copper strips were fitted to the circular faces of the disks and clips attached to the copper strips were used as leads. The leads were driven by a Keithley 2425 SMU set to 1 μV resolution and 10 NPLC averaging cycles to reduce noise. The current was swept from 100 mA to 1 A. All disks were isolated from the sample chuck using nonconductive, double-sided tape during measurements.

### Example Results

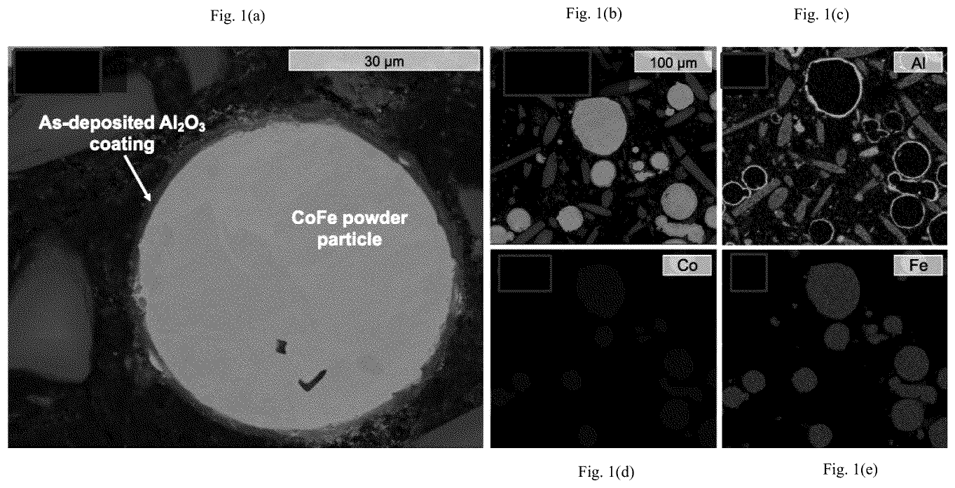

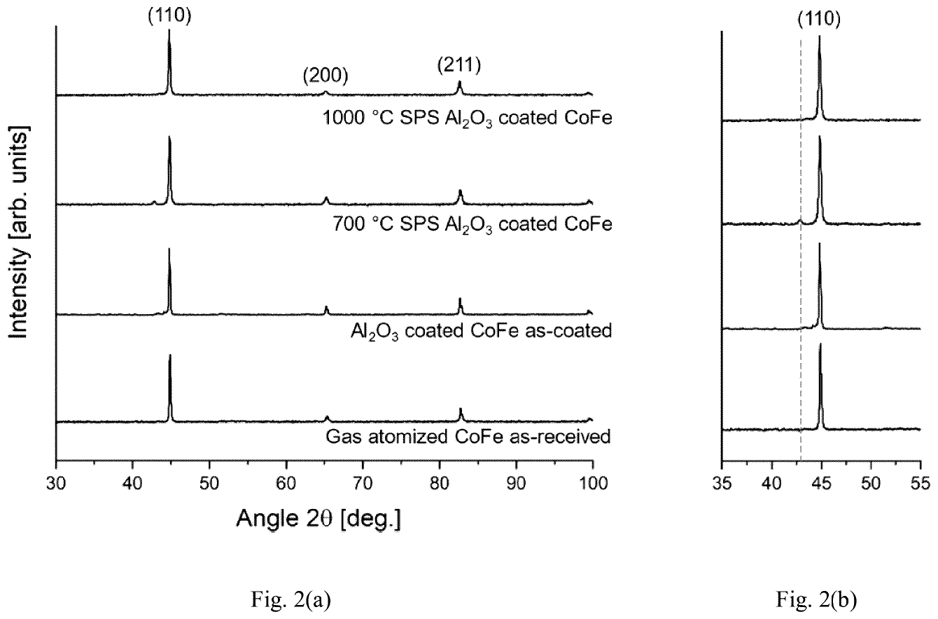

The SE micrograph and corresponding BSE micrograph and EDS elemental maps of the cross sections of as-coated powders are shown in FIGS. 1(a), (b), (c), (d), and (e), respectively. From the cross sections of the as-coated powder BSE micrograph in FIG. 1(a), spherical powder particles with particle size on the order of 10 μm are observed. Grain features can be observed in the BSE micrographs in FIGS. 1(a) and (b), revealing that the particles have an average grain size of 12 μm. In the BSE micrographs in FIGS. 1(a) and (b), the Al₂O₃ coating is observed as a dark gray phase surrounding powder particles. The Al₂O₃ coating is also observable in the EDS elemental map in FIG. 1(c), where it is clear that Al₂O₃ is fully coating the CoFe powder particles. The Al₂O₃ coating is approximately 2-5 μm thick. Lastly, it should be noted the Al-rich, needle-shaped particles observed in the EDS elemental map in FIG. 1(c) are artifacts of the KonductoMet™ polymer the powders are mounted in for cross-sectional polishing. In FIG. 2(a), the XRD pattern of the as-coated powders is plotted and compared with the SMCs made from the powders, consolidated at 700° C. and 1000° C. A closer view of the Al₂O₃ peak is shown and indicated in FIG. 2(b).

From the XRD pattern of the as-coated feedstock powders in FIGS. 2(a) and (b), additional Bragg's law satisfying peaks, corresponding to Al₂O₃ appear at 2θ angles of 40.289° and 44.097° in addition to the major BCC peaks for CoFe. The XRD patterns of the CoFe-Al₂O₃ composite consolidated at 700° C. and 1000° C. are also shown in FIGS. 2(a) and (b) for comparison with the as-coated powder before SPS consolidation. After SPS consolidation at 1000° C., the major peaks for a BCC CoFe structure are observed. Unlike the as-coated powder XRD pattern, an additional peak is not observable in FIG. 2(b) or indexed by the Rigaku SmartLab XRD software. Similar to the as-coated powder XRD pattern, the observed peaks are relatively narrow. Like the 1000° C. consolidated composite and the as-coated powder XRD patterns, the peaks of the 700° C. consolidated composite XRD pattern are relatively narrow and the major peaks for the BCC CoFe phase are observed. In addition to the major BCC peaks, in FIG. 2b, a peak corresponding to Al₂O₃ is observed at a 2θ angle of 42.764°. However, the additional peak in the 700° C. consolidated composite XRD pattern appears at a different 2θ angle than the additional peaks in the as-coated powder XRD pattern, likely due to a phase transformation of the Al₂O₃ (Feret F R, Roy D, Boulanger C (2000) Determination of alpha and beta alumina in ceramic alumina by X-ray diffraction, Spectrochim. Acta. Part B At Spectrosc 55:1051-1061. https://doi.org/10.1016/S0584-8547 (00) 002 25-1).

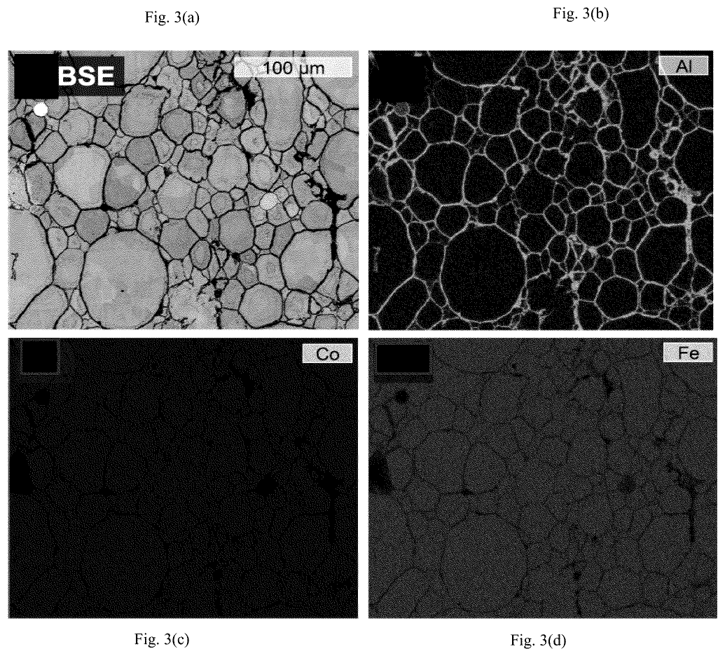

The BSE micrograph and corresponding EDS elemental maps of the cross section of the 1000° C. consolidated CoFe-Al₂O₃ composite are included in FIGS. 3(a), (b), (c), and (d), respectively.

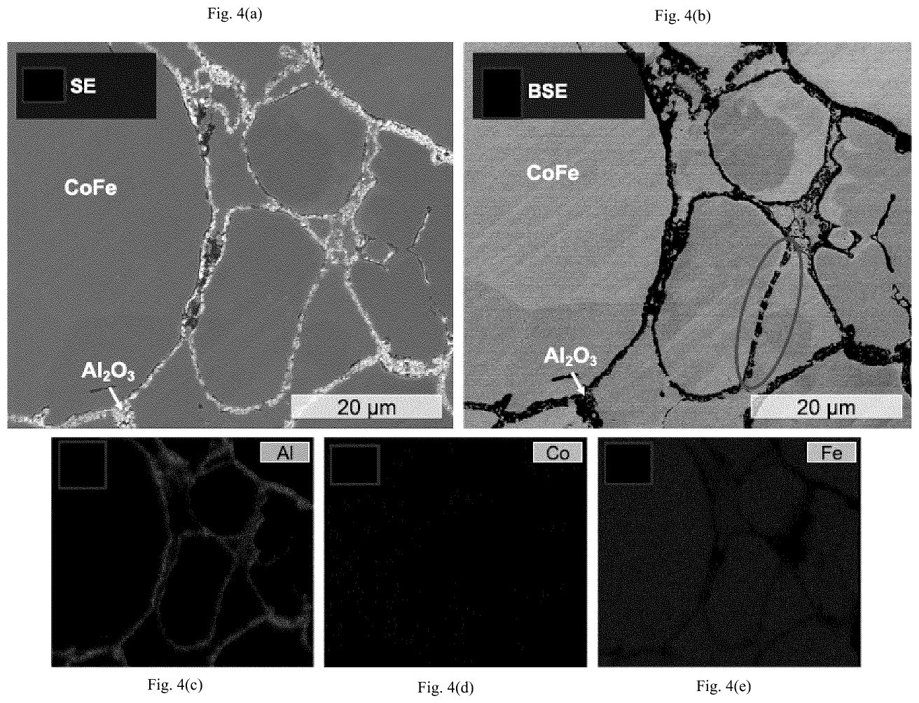

After SPS consolidation at 1000° C., the relative density of the SMC reached nearly 95%. In the BSE micrograph of the 1000° C. consolidated SMC in FIG. 3(a), consolidated powder particles, bounded by the Al₂O₃ coating, are observed. From the BSE micrograph and corresponding EDS elemental maps in FIGS. 3(a), (b), (c), and (d) the Al₂O₃ coating is distinctly observable from the CoFe powder by BSE contrast and EDS element detection. In the BSE micrograph, the Al₂O₃ phase appears nearly black and the CoFe phase appears light to medium gray with contrast within powder particles due to grain orientation. The coating is approximately 1-3 μm in thickness. Compared to the as-coated powder particles shown in FIGS. 1(a) and (b), the 1000° C. consolidated powders appear less spherical and more elongated, and the average particle size has increased to approximately 25 μm. Within the 1000° C. powder particles, the grains appear to be larger than grains in the as-coated powders and have a grain size of approximately 10 μm, the same order of magnitude as in the powder particles themselves. FIG. 3a also clearly shows that the powder particles consolidated at 1000° C. are slightly deformed and packed tightly with the Al₂O₃ phase uniformly coating the boundaries between particles. A SE micrograph and corresponding BSE micrograph and EDS elemental maps and point scans of the 1000° C. consolidated composite at higher magnification is shown for further analysis, in FIGS. 4(a), (b), (c), (d), (c), and (f), respectively.

The polished Al₂O₃ phase has a morphologically different surface topology and appears brighter than the polished CoFe powder particle cores in the SE micrograph. Some porosity is observable between powder particles in the Al₂O₃ phase, suggesting the Al₂O₃ is not fully densified. While some small, nanometer-scale pores are found within CoFe powder particles, most likely from the atomization process, the CoFe phase appears fully densified. Upon closer inspection of the boundaries between consolidated powder particles at high magnification, some CoFe is observed between powder particles in the Al₂O₃ coating regions. This CoFe perforation into the coating is circled in red in the BSE micrograph in FIG. 4(b) and can be observed upon close inspection of the EDS element maps in FIGS. 4(c), (d), and (c).

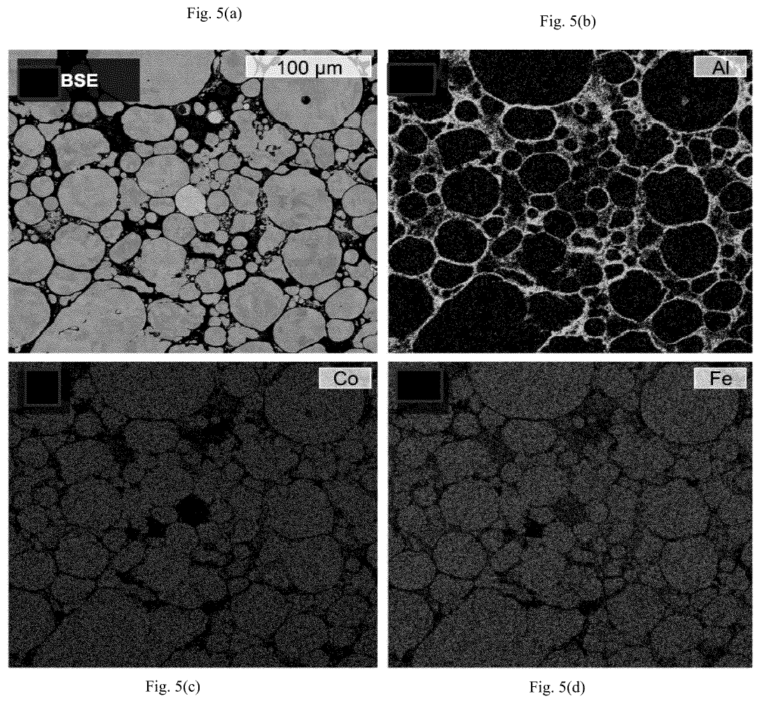

The BSE micrograph and corresponding EDS elemental maps of the 700° C. consolidated composite are shown in FIGS. 5(a)-5(d), respectively.

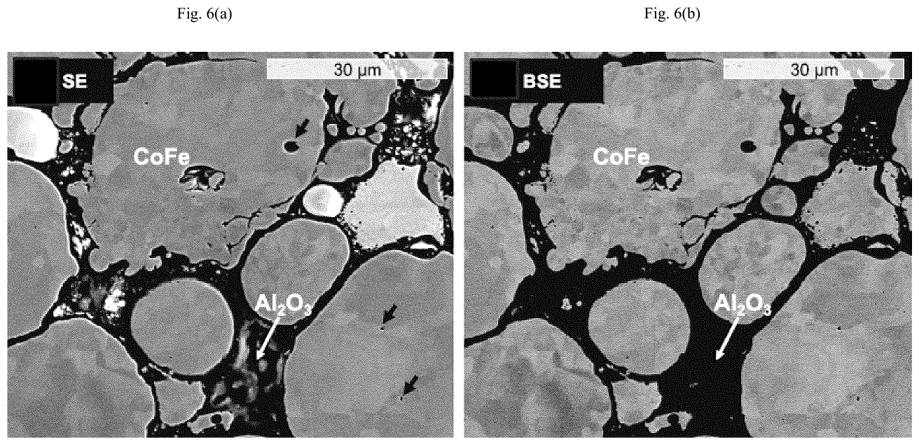

In the BSE micrograph, in FIG. 5(a), the Al₂O₃ phase, coating powder particles, appears nearly black and the CoFe particles appear light to medium gray with some contrast within powder particles due to grain orientation. The continuous Al₂O₃ coating of non-uniform thickness is observed between CoFe powder particles in the BSE micrograph and corresponding EDS element maps. The relative density of the 700° C. consolidated composite was only approximately 82%, less dense than the 1000° C. consolidated composite and appeared more porous in the Al₂O₃ phase in the electron micrographs as well. This is apparent in the regions between powder particles which are both black in the BSE micrograph and appear to have low Al content in the corresponding EDS map. Compared to the 1000° C. consolidated composite, the powders are more loosely packed in the 700° C. consolidated composite. In the EDS element maps in FIGS. 5(b)-5(d), no CoFe is detected perforating the Al₂O₃ phase regions between powder particles. A higher-magnification SE micrograph and corresponding BSE micrograph is shown in FIGS. 6(a) and (b), respectively.

From the SE micrograph in FIG. 6(a), isolated pores are observed (black arrows) within powder particle interiors. Between particles, and at triple junctions especially, voids and gaps in the Al₂O₃ coating are observed in the SE micrograph. Analysis of seventeen SE micrographs of the cross sections of the 700° C. SPS consolidated samples, at magnifications of 250×, 500×, and 1000×, reveals the volume fraction of the porosity is estimated to be approximately 18.89%. However, it should be noted that the threshold and analysis of the micrograph does not perfectly distinguish between porosity and the Al₂O₃ phase which can both appear dark in the micrographs. Additionally, some of the porosity in the micrograph may actually be due to pull-out of the Al₂O₃ phase during mechanical polishing and may not reflect the true density of the SMC. From both FIGS. 5(a) and 6(a), powder particles bounded by the Al₂O₃ coating are observed on the order of 10 μm. Within the powder particles, grain features are observed to be ˜10 μm, as in the as-coated powders. Lastly, in the SE micrograph in FIG. 6(a), some powder particles appear bright, but showed no compositional difference in the corresponding BSE micrographs or EDS element maps.

The measured magnetic and electronic properties and relative densities of the consolidated CoFe—Al₂O₃ composites are reported in Table 1.

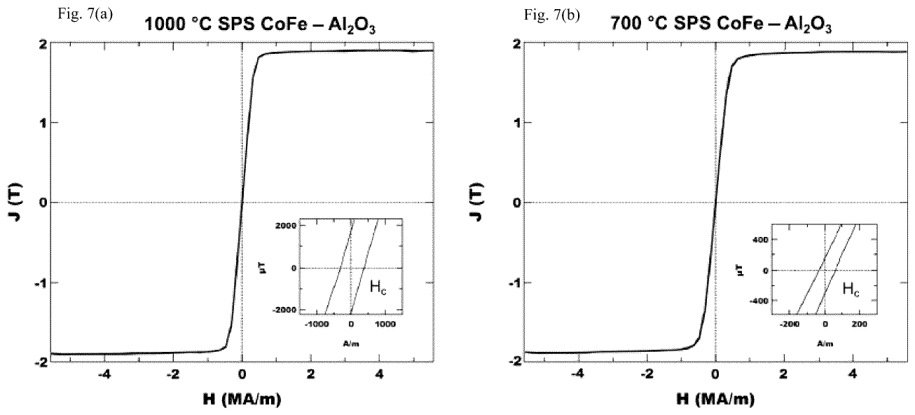

Properties of the as-received coated and uncoated CoFe powders and SMCs from the previous literature are also shown in Table 1 for reference. The 1000° C. consolidated composite reached a measured Jₛ of 1.90 T, slightly higher than the Jₛ reported for the 700° C. consolidated composite. Both consolidated composites in this study had a noticeably greater Jₛ than previous SMCs, but not compared to the CoFe alloy, which was expected. The 700° C. sample achieved an electrical resistivity several orders of magnitude higher than the 1000° C. consolidated CoFe—Al₂O₃ composite from this work and the equiatomic CoFe alloy. The DC hysteresis curves of the consolidated SMCs are shown in FIGS. 7(a) and (b). From FIGS. 7(a) and (b), the coercivity of the 700° C. CoFe—Al₂O₃ composite was approximately an order of magnitude less than the composite consolidated at 1000° C. As reported in Table 1, the Jₛ of both SMCs is less than 2.0 T. It has been shown that far greater resistivities were previously achieved in SMCs, at the cost of lowered Jₛ. Ultimately, the Jₛ of the composites in this study was slightly lowered compared to previous reports of the equiatomic CoFe alloy. However, the Jₛ achieved remained higher than that of SMCs produced in previous studies because CoFe was used as the ferromagnetic phase as opposed to Fe or Fe—Si. While a change in Jₛ, proportional to the change in relative density was expected, a smaller shift in Jₛ was observed, suggesting the CoFe phase was fully densified at both temperatures, yielding little change. In this study, compared to the CoFe alloy, a dramatically increased resistivity was achieved by consolidating Al₂O₃-coated CoFe powders. The electrical resistivity achieved in this SMC is within typical limits of previous SMC studies.

Table 1: Measured properties and relative densities of the as-received coated and uncoated CoFe powder as well as the consolidated CoFe—Al₂O₃ composites from this study, along with previously reported properties of SMCs for comparison. Values of magnetic saturation are reported for the loose powders since Jₛ is a volumetric, density dependent measurement

| | Saturation | | | Through | |
|---|---|---|---|---|---|
| | polarization (Jₛ) | Magnetic saturation | Coercivity | resistivity (ρ) | Relative density (% |
| Sample | [T] | (M [symbol] ) [ [symbol] · m²/kg] | (H [symbol] ) ( [symbol] /m) | [μΩ · m] | of theoretical) |
| As-received CoFe | n.a | 219 ± 1.6 | 1050 ± 6.1 | n.a | n.a |
| As-coated CoFe—Al₂O₃ | n.a | 218 ± 1.6 | 555 ± 6.1 | n.a | n.a |
| 1000° C. SPS CoFe—Al₂O₃ | 1.90 ± 0.01 | 194 ± 1.6 | 382 ± 6.1 | 0.20 ± 7.19 | 94.69 ± 0.24 |
| 700° C. SPS CoFe—Al₂O₃ | 1.88 ± 0.01 | 227 ± 1.6 | 98.9 ± 6.1 | 135.49 ± 7.19 | 82.54 ± 0.24 |
| SMC from the previous | 0.3-1.8 | n.a | 150-400 | 100-30,000 | n.a |
| literature [3, 6-12, 15-20] | | | | | |

[symbol]

indicates data missing or illegible when filed

### Discussion

The 1000° C. consolidated composite achieved a high relative density, nearly 95%, and is attributed to the high SPS temperature used which allowed more sintering and consolidation of the Al₂O₃ phase. There may be some discrepancy in the calculated relative density and the observed porosity in the SE micrographs because the phase fraction of the Al₂O₃ coating was targeted to be 2 vol. % Al₂O₃ in the powders but may differ in the composites due to the distribution of powder particle sizes and thus actual volume fractions of the Al₂O₃ phase. At 1000° C., the CoFe phase appears to be fully densified, suggesting differences in density are due to partial densification of Al₂O₃ during SPS. In the SE micrograph in FIG. 4(a), the porosity observed within powder particles is on the nanometer scale and is common in gas atomized powders even near fully dense. At 1000° C., 0.5 Tₘₑₗₜ of Al₂O₃ and 0.66 Tₘₑₗₜ of CoFe was reached allowing full sintering of the CoFe metal, but only partial sintering of the Al₂O₃ phase. Additionally, any thermal expansion of the graphite dies during SPS consolidation may have caused increased uniaxial pressure above 150 MPa but the lower limit of the SPS prevented any reduction in the compressive load. The elongation and tight packing of powder particles as well as the interpenetration of the CoFe phase into the Al₂O₃ coating are attributed to the high temperature and pressure achieved during SPS. Furthermore, at a temperature above 0.5 Tₘₑₗₜ in metals, grain growth is expected and was observed in the CoFe phase of the 1000° C. consolidated composite (Porter D, Easterling K, Sherif M (2009) Phase transformations in metals and alloys, 3rd edn. CRC Press, Boca Raton). While CoFe and Al₂O₃ do not appear to have formed any new phase, as shown by the XRD pattern of the consolidated composite in FIG. 2 and Co and Fe have little to no solubility in Al₂O₃ so no new phases or reactions are expected to take place during consolidation of this SMC (Zhao J, Harmer M P (1987) Sintering of ultra-high-purity alumina doped simultaneously with MgO and FeO. J Am Ceram Soc 70:860-866. https://doi.org/10.1111/j.1151-2916. 1987.tb04906.x; Bataille A, Addad A, Crampon J, Duclos R (2005) Deformation behaviour of iron-doped alumina. J Eur Ceram Soc 25:857-862. https://doi.org/10.1016/j.jeurceramsoc.2004.01. 006; Rhee Y W, Lee H Y, Kang S J L (2003) Diffusion induced grain-boundary migration and mechanical property improvement in Fe-doped alumina. J Eur Ceram Soc 23:1667-1674. https://doi.org/10.1016/S0955-2219 (02) 004 00-4). However, in the BSE micrograph in FIG. 4(b) and the results of the EDS point scans shown in FIG. 4(f), the CoFe phase is observed perforating the Al₂O₃ boundary phase. It is most likely that the CoFe phase has undergone plastic deformation and flow causing interpenetration into and through the regions of the Al₂O₃ coating. In the previous literature describing the processing of functionally graded materials prepared through consolidation of coated and multiphase powders, viscoplastic deformation of the softer phase of a multiphase composite has been observed and analytically modeled, especially at contact points between the softer and harder phases (Stora✓kers B, Fleck N A, McMeeking R M (1999) The viscoplastic compaction of composite powders. J Mech Phys Solids 47:785-815. https://doi.org/10.1016/S0022-5096 (98) 00076-3; Mortensen A, Suresh S (1995) Functionally graded metals and metal-ceramic composites: part 1 processing. Int Mater Rev 40:239-265. https://doi.org/10.1179/imr. 1995.40.6.239). Furthermore, at temperatures as low as 0.4 Tₘₑₗₜ metals can begin to easily experience plastic deformation and creep, and at 1000° C., the CoFe phase is at nearly 0.67 Tₘₑₗₜ which would enable the plastic flow causing the interpenetration observed in FIG. 4b. Ultimately, from the previous literature and microstructural observations, it is clear the CoFe phase has perforated the Al₂O₃ phase when consolidated at 1000° C., suggesting the SMC has been over-consolidated, yet the Al₂O₃ phase appears only partially densified and sintered.

In the XRD pattern of the 700° C. consolidated composite in FIGS. 2(a) and (b), the major BCC CoFe peaks and an additional peak at a 2θ angle of 42.764° was observed. From the previous literature, the additional peak most likely corresponds to the hexagonal a phase of Al₂O₃. However, a different set of additional peaks appear in the XRD pattern of the as-coated powders, at 2θ angles of 40.2859° and 44.097°. The extra peaks in the as-coated powder most likely correspond to the metastable cubic y phase of Al₂O₃. The Al₂O₃ coating most likely undergoes a phase transformation from the metastable c phase to the stable hexagonal a phase, which has been shown to occur at elevated temperatures and pressures in several previous works (Steiner C, Hasselman D P H, Spriggs R M (1971) Kinetics of the Gamma-to-Alpha Alumina Phase Transformation. J Am Ceram Soc 54:412-413. https://doi.org/10.1111/j.1151-2916. 1971.tb12335.x; Balima F, Largeteau A (2019) Phase transformation of alumina induced by high pressure spark plasma sintering (HPSPS). Scr Mater 158:20-23. https://doi.org/10.1016/j.scripta mat.2018.08.016). Additionally, the proprietary chemical vapor deposition powder coating process is a nonequilibrium process which potentially resulted in the deposition of a metastable Al₂O₃ phase on the CoFe powder particles. From the XRD patterns in FIGS. 2(a) and (b), after consolidation at 700° C., no evidence of formation of a new phase with Co or Fe was observed.

Compared to the composite consolidated at 1000° C., after consolidating the coated powders at 700° C., little to no grain growth was observed in the electron micrographs in FIGS. 5(a) and 6(a) and (b). At only 700° C., the Al₂O₃ coating only reached 0.35 Tₘₑₗₜ which most likely prevented full sintering and consolidation of the coated Al₂O₃ phase. The large gaps and voids observed between particles in the continuous Al₂O₃ coating are further indications of only incomplete densification. While some gaps and voids are from particles which have fallen out of the sample during polishing, the fact that some particles are loosely bonded at all further suggests the Al₂O₃ phase was not fully consolidated at 700° C. Furthermore, the loose packing of the CoFe powder particles and thicker, more substantial Al₂O₃ phase at triple junctions between particles also suggests the Al₂O₃ phase was not fully densified. Additionally, the particles which appear brighter in the SE micrograph in FIG. 6(a) most likely emit high SE signal due to charging effects of trapped electrons in the SEM. These particles are most likely loosely bound and potentially able to fall out, preventing the flow of electrons into the rest of the microscopy sample. It is also possible the powder particles are well electrically insulated by the Al₂O₃ coating and isolated from the rest of the sample, also preventing the flow of electrons from the SEM beam through the sample. In either case, the presence of the bright particles further suggests incomplete densification of the Al₂O₃ phase at only 700° C. Ultimately, at only 700° C., a continuous Al₂O₃ phase intersecting CoFe particles was achieved and no new phases in the CoFe—Al₂O₃ composite were detected. However, the Al₂O₃ phase was not fully densified. Despite the incomplete densification of the CoFe—Al₂O₃ composite at 700° C., exceptional magnetic and electronic properties were observed.

In Table 1 and FIGS. 7(a) and (b), the magnetic properties of the 1000° C. and 700° C. consolidated composite showed significant decreases in Jₛ compared to the CoFe alloy; this is attributed to microstructural features of the material and the decreased volume fraction of the magnetic CoFe phase. An exceptionally high Jₛ can be achieved by the CoFe powder particles and is attributed to the interatomic spacing of the B2 ordered BCC CoFe structure and its electron concentration (Leary A M, Ohodnicki P R, Mchenry M E (2012) Soft magnetic materials in high-frequency, high-power conversion applications. JOM 64:772-781. https://doi.org/10.1007/s11 837-012-0350-0). The ordering of the CoFe alloy is a diffusionless transformation which occurs below 700° C.; therefore, both consolidated composites would contain B2 ordered CoFe powder particles (Clegg D W, Buckley R A (1973) The disorder? order transformation in iron-cobalt-based alloys. Met Sci J 7:48-54. https://doi.org/10.1179/030634573790445541; Hall R C (1960) Magnetic Anisotropy and Magnetostriction of Ordered and Disordered Cobalt-Iron Alloys J Appl Phys 31:157. https://doi.org/10.1063/1.1984643). However, the loose packing of powder particles, in other words, the low density of the SMC, can cause detrimental decreases to the Jₛ. The physical space and gaps between magnetic particles can prevent full magnetic alignment of domain walls in separated magnetic particles (Webster J G (2016) Wiley encyclopedia of electrical and electronics engineering. Wiley, New York. https://doi.org/10. 1002/047134608x). By significantly decreasing the volume fraction of the magnetic CoFe phase, and by physically separating the CoFe particles, the Al₂O₃ phase reduces the bulk Jₛ of the composite. The effect of the physical spacing between particles is more noticeable in the 700° C. consolidated composite as the Al₂O₃ phase appears far less dense than in the 1000° C. consolidated composite. However, both consolidated composites in this study achieved higher Jₛ than in previous SMCs and is attributed to the CoFe powder particles and relatively high densification achieved using SPS.

Because nearly full densification was achieved in the 1000° C. composite, 1.90 T may be the maximum threshold Jₛ for this composite without reducing the volume fraction of Al₂O₃. From this Jₛ of 1.90 T, using a law of mixtures calculation, it is estimated there is approximately 20% Al₂O₃ by volume in this SMC. The discrepancy from the targeted volume fraction of Al₂O₃ coated on CoFe powders is likely due to the broad particle size range consolidated in this study. Further improvement to the magnetic properties of the composite may be achieved by consolidating coated powders above a specific size range, effectively reducing the volume fraction of Al₂O₃ in the consolidated composite. Additionally, an increase in Jₛ proportional to the increase in density was expected, but a relatively low change in Jₛ is observed in the 1000° C. compared to the 700° C. consolidated SMC. This is likely because at both temperatures, the main Jₛ controlling phase, the CoFe, is fully densified at both 700° C. and 1000° C. The main difference in density is due to the Al₂O₃ phase, so less dramatic changes to Jₛ are observed. Additionally, the percolated CoFe phase in the Al₂O₃ boundary phase can act as smaller particles of a ferromagnetic phase and may cause disruptions to the magnetization and degradation of the achievable Jₛ of the CoFe phase. In general, decreases to Jₛ in SMCs compared to the CoFe alloy are expected and can be controlled with densification and Al₂O₃ volume fractions. The Jₛ reported of the SMCs in this study are exceptionally high compared to previous studies of SMCs and can be further improved upon in the future.

Compared to previously reported SMCs, the electrical resistivity of the CoFe—Al₂O₃ composite consolidated at 1000° C. is relatively low. Ultimately, large increases in electrical resistivity were not observed in the 1000° C. consolidated composite likely because of the flow of the CoFe phase into Al₂O₃ boundaries between particles. To further increase the resistivity, percolation of the CoFe phase into the insulating phase must be prevented. By contrast, in the 700° C. consolidated composite, the resistivity increased by nearly 4 orders of magnitude compared to the CoFe alloy. The dramatic increase to electrical resistivity is attributed to the retention of a continuous Al₂O₃ coating during SPS consolidation with no plastic flow of the CoFe phase into the Al₂O₃ boundary, and the relatively low density of the composite. Compared to previously reported SMCs, the electrical resistivity reported in the composite consolidated at 700° C. is relatively low, but still within the typical range. As discussed previously and shown in FIGS. 5(a) and (b) and 6(a) and (b), at 700° C., the composite was only partially densified. During SPS consolidation at 700° C., the CoFe particles remained fully bounded by the Al₂O₃ coating, effectively creating a continuous, yet porous phase of Al₂O₃ through the CoFe particles. The irregularities in the morphology of the Al₂O₃ phase at triple junctions and between particles prevents charge carrier conduction, increasing the bulk electrical resistivity measured through the composite. This increased resistivity can result in the reduction of eddy current losses in soft magnetics by minimizing eddy currents in the bulk SMC. Additionally, eddy current losses are further reduced by limiting the electrical domain size d to the size of coated powder particles as discussed with Eq. (1) previously. If eddy currents are produced in the bulk composite, the eddy current sizes will be confined to individual CoFe powder particles and significant eddy current losses can be prevented. Ultimately, dramatic increases to resistivity in the 700° C. consolidated composite, compared to the composite consolidated at 1000° C. and CoFe alloy are attributed to the SMC having a relatively low density and a fully continuous Al₂O₃ phase separating CoFe powder particles.

### CONCLUSIONS

A CoFe—Al₂O₃ composite was produced by consolidating Al₂O₃-coated CoFe powder particles via SPS, targeting a SMC with high Jₛ and high electrical resistivity. The powder particles were coated with a large-scale, proprietary coating deposition process. After SPS consolidation of the coated powders at 1000° C., decreases to the magnetic properties, proportional to the volume fraction of the Al₂O₃ phase and minimal changes to the electronic properties were observed compared to the CoFe alloy. The minimal changes to the electronic properties were attributed to the interpenetration of the CoFe phase into the Al₂O₃ coatings between powder particles during SPS. At 1000° C., plastic flow of the CoFe phase is activated and percolated through the Al₂O₃ phase. The composite consolidated at 700° C. displayed an exceptional combination of high Jₛ, 1.88 T, and high electrical resistivity, 135μΩ·m, and the properties were attributed to the SMC having relatively low density in the Al₂O₃ and a continuous Al₂O₃ coating surrounding CoFe powder particles. Further densification of the CoFe—Al₂O₃ composite after consolidation at 700° C., without uncontrolled percolation of the CoFe phase into the Al₂O₃ phase, may further improve magnetic properties of the composite. In the future, the consolidation of larger powder particle size ranges can reduce the volume fraction of Al₂O₃ and further target improved soft magnetic properties. However, larger powder particle sizes and therefore lowered Al₂O₃ volume fractions may result in reduced electrical resistivity of the final SMC. In this study, the focus was magnetic and electronic properties of these consolidated composites; future studies exploring mechanical behavior of the composite are recommended to further develop the CoFe—Al₂O₃ composite and others like it for widespread soft magnetic applications. The efficiency of soft magnetic materials may be increased by controlling secondary phase fractions and morphologies and constituent element diffusion in SMCs.

The herein described subject matter sometimes illustrates different components contained within, or connected with, different other components. It is to be understood that such depicted architectures are illustrative, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably coupleable,” to each other to achieve the desired functionality. Specific examples of operably coupleable include but are not limited to physically mateable and/or physically interacting components and/or wirelessly interactable and/or wirelessly interacting components and/or logically interacting and/or logically interactable components.

With respect to the use of plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.).

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

It will be further understood by those within the art that if a specific number of an introduced claim recitation is intended, such an intent will be explicitly recited in the claim, and in the absence of such recitation, no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general, such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

Further, unless otherwise noted, the use of the words “approximate,” “about,” “around,” “substantially,” etc., mean plus or minus ten percent.

Although the present embodiments have been particularly described with reference to preferred examples thereof, it should be readily apparent to those of ordinary skill in the art that changes and modifications in the form and details may be made without departing from the spirit and scope of the present disclosure. It is intended that the appended claims encompass such changes and modifications.

What is claimed is:

1. A magnetic material comprising:
a soft magnetic composite comprised of coated powders, the coated powders including:
CoFe powders, and
Al₂O₃ coating on the CoFe powders.

2. The magnetic material of claim 1,
wherein the CoFe powders and Al₂O₃ coating are obtained through powder metallurgical processing.

3. The magnetic material of claim 1, soft magnetic composite is configured to achieve both high saturation magnetic polarization and high electrical resistivity.

4. The magnetic material of claim 3, wherein the soft magnetic composite is further configured to exhibit unique properties due to the relatively thick Al₂O₃ coating on CoFe powders which acts as an electrically insulative barrier between powder particles.

5. The magnetic material of claim 1, wherein the coated powders are consolidated using a specific sintering process.

6. The magnetic material of claim 1, wherein the coated powders are consolidated using standard powder consolidation processes.

7. The magnetic material of claim 1, wherein the CoFe powders comprise CoFe particles with a particle size below 150 μm.

8. The magnetic material of claim 1, wherein the CoFe powders comprise CoFe particles with a particle size in a range of about 20 to 150 μm.

9. The magnetic material of claim 1, wherein the Al₂O₃ coating is about 2 to 5 μm thick.

10. The magnetic material of claim 7, wherein the Al₂O₃ coating is about 2 to 5 μm thick.

11. The magnetic material of claim 8, wherein the Al₂O₃ coating is about 2 to 5 μm thick.

12. The magnetic material of claim 1, wherein the CoFe powders comprise gas atomized, pre-alloyed equiatomic CoFe powder particles.

13. A method of obtaining a magnetic material, comprising:
preparing CoFe powder particles;
coating the CoFe powder particles with Al₂O₃ to obtain coated powders; and
consolidating the coated powders to form a soft magnetic composite material.

14. The method of claim 13, wherein the CoFe powder particles have a particle size below 150 μm.

15. The method of claim 13, wherein the CoFe powder particles have a particle size in a range of about 20 to 150 μm.

16. The method of claim 13, wherein an Al₂O₃ coating of the coated powders is about 2 to 5 μm thick.

17. The method of claim 13, wherein the CoFe powder particles comprise gas atomized, pre-alloyed equiatomic CoFe powder particles.

18. The method of claim 13, wherein the coating is performed using a chemical vapor deposition process.

19. The method of claim 13, wherein the consolidating is performed between about 700° C. and 1000° C. under a vacuum of less than 5 Pa.
